(19) United States
(12) Patent Application Publication
(10) Pub. No.: US 2014/0357068 A1
(43) Pub. Date: Dec. 4, 2014

(54) PLASMA DOPING APPARATUS, PLASMA DOPING METHOD, SEMICONDUCTOR DEVICE MANUFACTURING METHOD AND SEMICONDUCTOR DEVICE

(71) Applicant: TOKYO ELECTRON LIMITED, Tokyo (JP)

(72) Inventors: Masahiro Horigome, Miyagi (JP); Hirokazu Ueda, Miyagi (JP); Masahiro Oka, Miyagi (JP); Yuuki Kobayashi, Miyagi (JP); Takayuki Karakawa, Miyagi (JP)

(73) Assignee: TOKYO ELECTRON LIMITED, Tokyo (JP)

(21) Appl. No.: 14/371,609

(22) PCT Filed: Oct. 19, 2012
(86) PCT No.: PCT/JP2012/077130

§ 371 Date: Jul. 10, 2014

(30) Foreign Application Priority Data
Jan. 13, 2012 (JP) 2012-004959
Oct. 2, 2012 (JP) 2012-220099

(51) Int. Cl. H01L 21/223; C23C 16/452

(52) U.S. Cl. CPC H01L 21/2236; C23C 16/452
USPC 438/513; 118/723 R; 118/723 MW

(57) ABSTRACT

A plasma doping apparatus which performs doping by injecting dopants into a substrate to be processed. The apparatus includes a processing container, a gas supplying unit configured to supply a doping gas and an inert gas for plasma excitation into the processing container, a holding table configured to hold the substrate to be processed, a plasma generating mechanism configured to generate plasma in the processing container using a microwave, a pressure adjusting mechanism configured to adjust a pressure in the processing container, and a control unit configured to control the plasma doping apparatus. The control unit controls the pressure adjusting mechanism to set the pressure in the processing container to be equal to or more than 100 mTorr and less than 500 mTorr such that a plasma processing is performed on the substrate to be processed using the plasma generated by the plasma generating mechanism.

### TECHNICAL FIELD

The present disclosure relates to a plasma doping apparatus, a plasma doping method, a semiconductor device manufacturing method and a semiconductor device.

### BACKGROUND

When semiconductor devices, such as LSIs (Large Scale Integrated circuits), MOS (Metal Oxide Semiconductor) transistors and the like, are manufactured by performing a variety of processing such as doping, etching, chemical vapor deposition (CVD) and sputtering on a semiconductor substrate (wafer), as a substrate to be processed.

One of techniques for injecting dopants into a substrate to be processed is disclosed in Japanese Patent Laid-Open Publication No. 2010-519735 (Patent Document 1).

### PRIOR ART DOCUMENT

### Patent Document

Patent Document 1: Japanese Patent Laid-Open Publication No. 2010-519735

### DISCLOSURE OF THE INVENTION

### Problems to be Solved

According to Patent Document 1, the doping is performed at a pressure in a processing container adjusted to fall within a range of 10 mTorr to 95 mTorr. When the doping is performed under such a relatively low pressure, it may be likely to have an adverse effect on the substrate to be processed, into which the dopants are to be injected, such as doing damage to the substrate. Specifically, for example, doping for the substrate to be processed to form a fin field effect transistor (FinFET) type semiconductor device having a three-dimensional (3D) structure may cause a shoulder drop state (or erosion) in which a so-called shoulder is cut away, which may result in damage to a physical shape. Therefore, there is a need for doping to make an adverse effect, such as damage to a substrate to be processed, as small as possible.

In addition, in a case where a doping object having a 3D structure, particularly such as a FinFET type semiconductor device, is subjected to doping, there is a need to equalize doping depths over the entire surface of a doping object when dopants are injected into the doping object. That is, there is a need for high doping conformality (uniformity).

### Means to Solve the Problems

According to an aspect, the present disclosure provides a plasma doping apparatus which performs doping by injecting dopants into a substrate to be processed. The apparatus includes a processing container in which dopants are injected into the substrate to be processed; a gas supplying unit configured to supply a doping gas and an inert gas for plasma excitation into the processing container; a holding table disposed in the processing container and configured to hold the substrate to be processed; a plasma generating mechanism configured to generate plasma in the processing container using a microwave; a pressure adjusting mechanism configured to adjust a pressure in the processing container; and a control unit configured to control the plasma doping apparatus. The control unit controls the pressure adjusting mechanism to set the pressure in the processing container to be equal to or more than 100 mTorr and less than 500 mTorr such that a plasma processing is performed on the substrate to be processed using the plasma generated by the plasma generating mechanism.

With this configuration, in the plasma doping, plasma is generated by the plasma generating mechanism using a microwave and the pressure in the processing container is set to be equal to or more than 100 mTorr and less than 500 mTorr such that the plasma processing is performed on the substrate to be processed. Accordingly, it is possible to subject a substrate to be processed, which is a doping object, to plasma doping which is capable of preventing damage to the substrate to be processed and providing high conformality for the substrate to be processed.

Further, the control unit may control the pressure adjusting mechanism to set the pressure in the processing container to be equal to or less than 450 mTorr.

Further, the control unit may control the pressure adjusting mechanism to set the pressure in the processing container to equal to or more than 150 mTorr and equal to less than 250 mTorr.

Further, after the plasma processing is performed on the substrate to be processed, the control unit may control the pressure in the processing container to be set to a pressure lower than the pressure set when the plasma processing is performed on the substrate to be processed such that another plasma processing is performed on the substrate to be processed using the generated plasma.

Further, the pressure lower than the pressure set when the plasma processing is performed on the substrate to be processed may be less than 100 mTorr.

Further, the doping gas may include at least one gas selected from a group consisting of B₂H₆, PH₃, AsH₃, GeH₄, CH₄, NH₃, NF₃, N₂, HF, and SiH₄.

Further, the inert gas for plasma excitation may include at least one gas selected from a group consisting of He, Ne, Ar, Kr, and Xe.

Further, the plasma generating mechanism may be provided with a microwave generator configured to generate a microwave for plasma excitation, a dielectric window configured to transmit the microwave generated by the microwave generator through the processing container, and a slot antenna plate formed with a plurality of slot holes and configured to emit the microwave to the dielectric window.

Further, the plasma generated by the plasma generating mechanism is generated by a radial line slot antenna.

According to another aspect, the present disclosure provides a plasma doping method of performing doping by injecting dopants into a substrate to be processed. The method includes holding a substrate to be processed on a holding table disposed in a processing container; supplying a doping gas and an inert gas for plasma excitation into the processing container; generating plasma in the processing container using a microwave; and setting a pressure in the processing container to be equal to or more than 100 mTorr and less than 500 mTorr, thereby performing a plasma processing on the substrate to be processed.

Further, the pressure in the processing container may be set to be equal to or less than 450 mTorr, thereby performing the plasma processing on the substrate to be processed.

Further, the pressure in the processing container may be set to be equal to or more than 150 mTorr and equal to less than 250 mTorr, thereby performing the plasma processing on the substrate to be processed.

Further, after the plasma processing is performed on the substrate to be processed, the pressure in the processing container may be controlled to be set to a pressure lower than the pressure set when the plasma processing is performed on the substrate to be processed such that another plasma processing is performed on the substrate to be processed using the generated plasma.

Further, the pressure lower than the pressure set when the plasma processing is performed on the substrate to be processed may be less than 100 mTorr.

Further, the doping gas may include at least one selected gas from a group consisting of B₂H₆, PH₃, AsH₃, GeH₄, CH₄, NH₃, NF₃, N₂, HF and SiH₄.

Further, the inert gas for plasma excitation may include at least one gas selected from a group consisting of He, Ne, Ar, Kr and Xe.

Further, the plasma generated by the plasma generating mechanism may be generated by a radial line slot antenna.

According to still another aspect, the present disclosure provides a method of manufacturing a semiconductor device by injecting dopants into a substrate to be processed. The method includes holding a substrate to be processed on a holding table disposed in a processing container; supplying a doping gas and an inert gas for plasma excitation into the processing container; generating plasma in the processing container using a microwave; and setting a pressure in the processing container to be equal to or more than 100 mTorr and less than 500 mTorr, thereby performing a plasma processing on the substrate to be processed.

According to still yet another aspect, the present disclosure provides a semiconductor device manufactured by injecting dopants into a substrate to be processed. The semiconductor device is manufactured by a process including holding a substrate to be processed on a holding table disposed in a processing container; supplying a doping gas and an inert gas for plasma excitation into the processing container; generating plasma in the processing container using a microwave; and setting a pressure in the processing container to be equal to or more than 100 mTorr and less than 500 mTorr, thereby performing a plasma processing on the substrate to be processed.

According to further aspect, the present disclosure provides a semiconductor device having a normalized value of equal to or more than 0.1, which is obtained by normalizing a peak area of Si—H bond of a silicon 2p spectrum with a peak area of a silicon substrate.

According to further aspect, the present disclosure provides a plasma doping method of performing doping by injecting dopants into a substrate to be processed, including: holding a substrate to be processed on a holding table which is disposed in a processing container; supplying an arsenic (As)-containing doping gas and an inert gas for plasma excitation into the processing container; generating plasma in the processing container using a microwave; and setting a pressure in the processing container to be equal to or more than 100 mTorr and less than 500 mTorr and establishing a relationship of 5.0E+13 m⁻²·sec⁻¹<flux F₁ of As atoms supplied in a direction perpendicular to the substrate to be processed<1.0E+14 m⁻²·sec⁻¹, thereby performing a plasma processing on the substrate to be processed.

Further, the plasma processing may be performed on the substrate to be processed by setting the pressure in the processing container to be equal to or more than 100 mTorr and less than 150 mTorr and establishing a relationship of 7.0E+13 m⁻²·sec⁻¹<flux F₁ of As atoms supplied in a direction perpendicular to the substrate to be processed<9.0E+13 m⁻²·sec⁻¹.

Further, the plasma processing may be performed on the substrate to be processed by supplying hydrogen at a flow rate of equal to or more than 1 sccm and equal to or less than 2.5 sccm, assuming that the total flow rate of the doping gas and the inert gas for plasma excitation is 1000 sccm.

### Effect of the Invention

According to the present disclosure, plasma is generated by a plasma generating mechanism using a microwave and a pressure in a processing container is set to be equal to or more than 100 mTorr and less than 500 mTorr, thereby performing a plasma processing on a substrate to be processed. Accordingly, it is possible to subject a substrate to be processed serving as a doping object to plasma doping which is capable of preventing damage to the substrate to be processed and providing high conformality for the substrate to be processed.

### BRIEF DESCRIPTION OF THE DRAWINGS

FIG. 1 is a schematic perspective view illustrating a portion of a FinFET type semiconductor device.

FIG. 2 is a schematic sectional view illustrating main parts of a plasma doping apparatus used for a semiconductor device manufacturing method according to one exemplary embodiment of the present disclosure.

FIG. 3 is a schematic view illustrating a slot antenna plate included in the plasma doping apparatus illustrated in FIG. 2 when viewed from the direction of arrow III in FIG. 2.

FIG. 4 is a flow chart schematically illustrating a plasma doping method according to one exemplary embodiment of the present disclosure.

FIG. 5 is an electron micrograph showing a magnified portion of a FinFET type semiconductor device when the pressure in a processing container is set to 200 mTorr.

FIG. 6 is an electron micrograph showing a magnified portion of a FinFET type semiconductor device when the pressure in a processing container is set to 750 mTorr.

FIG. 7 is a sectional view illustrating a portion of the section of a FinFET type semiconductor device.

FIG. 8 is a graph illustrating plasma doping depth ratios.

FIG. 9 is a schematic view illustrating a case where an ion injection apparatus is used to perform a doping on a fin of a FinFET type semiconductor device.

FIG. 10 is a schematic view illustrating a case where a plasma doping apparatus according to one exemplary embodiment of the present disclosure is used to perform a plasma doping.

FIG. 11 is a flow chart schematically illustrating a plasma doping method according to another exemplary embodiment of the present disclosure.

FIG. 12 is a graph showing waveform components of Si 2p3/2 spectrum when a cleaning processing is performed on a substrate to be processed using DHF.

FIG. 13 is a graph showing a relationship between a reduction rate of a peak area of a P 2p spectrum and a peak area ratio of Si—H bond normalized with Si—Si bond of a Si 2p spectrum.

FIG. 14 is a schematic sectional view illustrating a portion of a MOS type semiconductor device according to still another exemplary embodiment of the present disclosure.

FIG. 15 is a graph illustrating a relationship between a position and a sheet resistance of a substrate to be processed W when a flow rate of doping gas is changed, showing a vertical axis range of 0 to 14,000 Ω/cm².

FIG. 16 is a graph illustrating a relationship between a position and a sheet resistance of a substrate to be processed W when a flow rate of doping gas is changed, showing a vertical axis range of 0 to 800 Ω/cm².

FIG. 17 is a graph illustrating a relationship between a flow rate of AsH₃ in a doping gas and sheet resistance.

FIG. 18 is a graph showing a relationship between a position and a sheet resistance of a substrate to be processed W when a flow ratio of center gas/edge gas is changed.

FIG. 19 is a view illustrating a distribution of a sheet resistance when a flow ratio of center gas/edge gas=70/30.

FIG. 20 is a view illustrating a distribution of a sheet resistance when a flow ratio of center gas/edge gas=50/50.

FIG. 21 is a view illustrating a distribution of a sheet resistance when a flow ratio of center gas/edge gas=30/70.

FIG. 22 is a view illustrating a distribution of a sheet resistance when a flow ratio of center gas/edge gas=20/80.

FIG. 23 is a view illustrating a distribution of a sheet resistance when a flow ratio of center gas/edge gas=10/90.

FIG. 24 is a graph showing a relationship between a position and a sheet resistance of a substrate to be processed W when hydrogen is added, showing a vertical axis range of 0 to 3,000 Ω/cm².

FIG. 25 is a graph showing a relationship between a position and a sheet resistance of a substrate to be processed W when hydrogen is added, showing a vertical axis range of 0 to 200 Ω/cm².

### DETAILED DESCRIPTION TO EXECUTE THE INVENTION

Hereinafter, exemplary embodiments of the present disclosure will be described with reference to the accompanying drawings. A configuration of a semiconductor device according to one exemplary embodiment of the present disclosure will first be described.

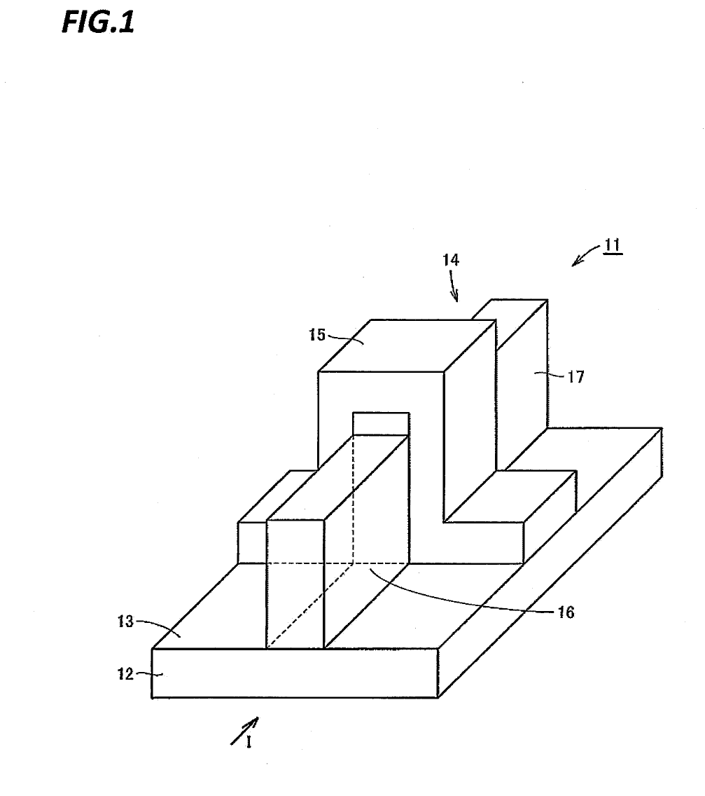

FIG. 1 is a schematic perspective view illustrating a portion of a FinFET type semiconductor device according to one exemplary embodiment of the present disclosure. Referring to FIG. 1, a FinFET type semiconductor device 11 according to one exemplary embodiment of the present disclosure includes a fin 14 formed to project upward from a surface 13 of a silicon substrate 13. The direction of extension of the fin 14 is as indicated by an arrow I in FIG. 1. The fin 14 has substantially a rectangular shape when viewed from the direction of the arrow I corresponding to the horizontal direction of the FinFET type semiconductor device 11. A portion of the fin 14 is covered to form a gate 15 extending in a direction perpendicular to the extension direction of the fin 14. In the fin 14, a source 16 is formed in the front side of the formed gate 15 and a drain 17 is formed in the inner side of the gate 15. This shape of the fin 14, i.e., a surface of the portion projecting upward from the surface 13 of the silicon substrate 12, is subjected to doping by plasma generated using a microwave.

In addition, although not illustrated in FIG. 1, in a semiconductor device manufacturing process, a photoresist layer may be formed before a plasma doping step. The photoresist layer is formed in a lateral side of the fin 14 at a predetermined interval, for example, in a portion located in the horizontal direction in FIG. 1. The photoresist layer is formed to extend in the same direction as the fin 15 and project upward from the surface 13 of the silicon substrate 12.

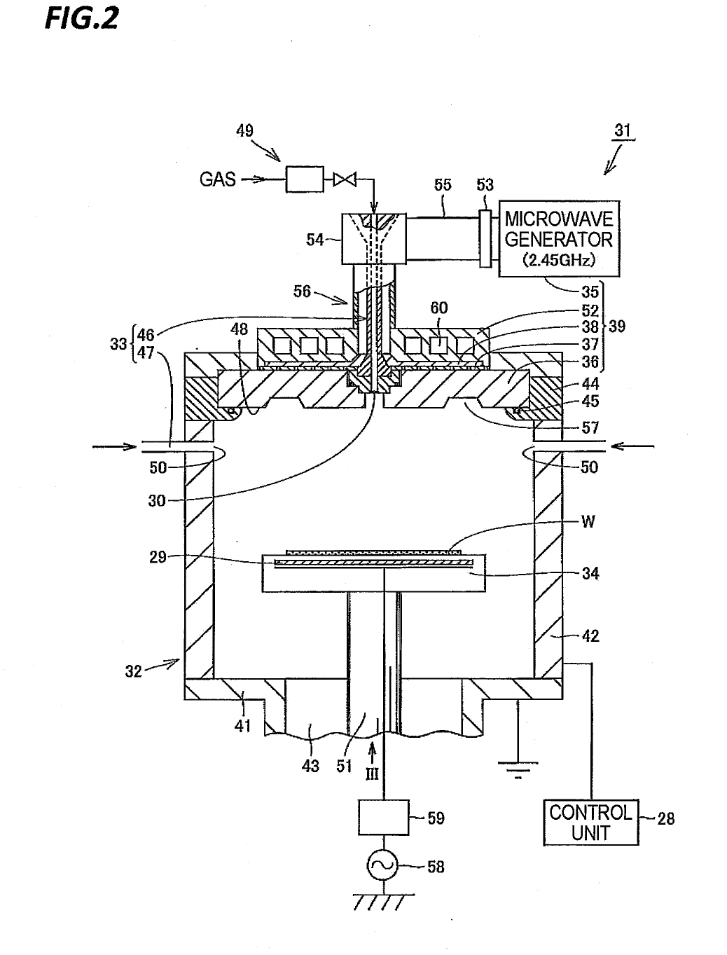

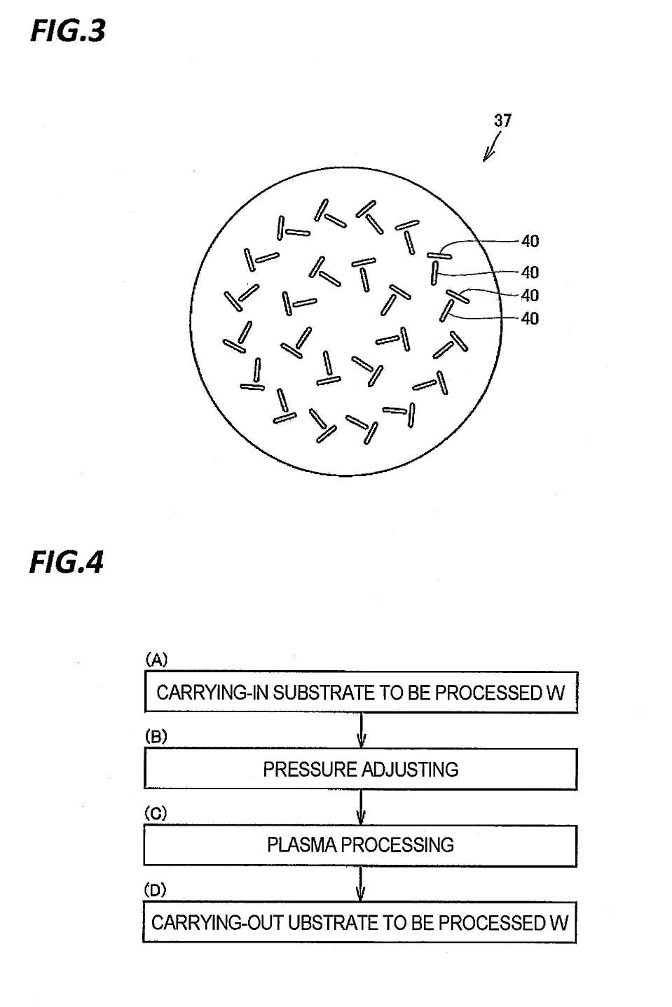

FIG. 2 is a schematic sectional view illustrating main parts of a plasma doping apparatus according to one exemplary embodiment of the present disclosure. FIG. 3 is a view illustrating a slot antenna plate included in the plasma doping apparatus illustrated in FIG. 2 when viewed from below, i.e., when viewed in a direction of arrow III in FIG. 2. For the purpose of ease of understandings, hatching of portions of some members is not illustrated in FIG. 2. In this exemplary embodiment, the vertical direction on the paper in FIG. 2 is assumed to be the vertical direction in the plasma doping apparatus.

Referring to FIGS. 2 and 3, a plasma doping apparatus 31 includes a processing container 32 in which a plasma doping is performed on a substrate to be processed W, a gas supplying unit 33 which supplies a plasma excitation gas or a doping gas serving as a source of dopants into the processing container 32, a disc-like holding table 34 on which the substrate to be processed W is held, a plasma generating mechanism 39 which generates plasma in the processing container 32 using a microwave, a pressure adjusting mechanism which adjusts a pressure in the processing container 32, and a control unit 28 which controls the overall operation of the plasma doping apparatus 31. The control unit 28 controls the overall parameters of the plasma doping apparatus 31, such as a flow rate in the gas supplying unit 33 and the pressure in the processing container 32.

The processing container 32 includes a bottom portion 41 located below the holding table 34 and a side wall 42 extending upward from the circumference of the bottom portion 41. The side wall 42 has substantially a cylindrical shape. The bottom portion 41 of the processing container 32 is formed with a penetrating exhaust hole 43. The upper side of the processing container 32 is opened and the processing container 32 is configured to be air-tightly sealed by a cover unit 44 disposed in the upper side of the processing container 32, a dielectric window 36 which will be described later, and an O-ring 45 serving as a seal member interposed between the dielectric window 36 and the cover unit 44.

The gas supplying unit 33 includes a first gas supplying part 46 which ejects a gas to the center of the substrate to be processed W, and a second gas supplying part 47 which ejects a gas from the outside of the substrate to be processed W. In the first gas supplying part 46, a gas supplying hole 30 for supplying the gas is formed in the center of the dielectric window 36 in the radial direction at a position retreated to the inside of the dielectric window 36 from the bottom 48 of the dielectric window 36 which faces the holding table 34. The first gas supplying part 46 supplies an inert gas for plasma excitation or a doping gas while regulating a flow rate or the like by means of a gas supplying system 49 connected to the first gas supplying part 46. The second gas supplying part 47 is formed by forming a plurality of gas supplying holes 50 for supplying an inert gas for plasma excitation or a doping gas into the processing container 32 in a portion of the upper side of the side wall 42. The plurality of gas supplying holes 50 is formed at the same intervals in the circumferential direction. The same kind of inert gas for plasma excitation or doping gas is supplied from the same gas source to the first gas supplying part 46 and the second gas supplying part 47. Depending on requirements, control contents, etc., separate gases may be supplied from the first gas supplying part 46 and the second gas supplying part 47 and may be regulated in terms of flow ratio and the like.

In the holding table 34, a high-frequency power supply 59 for RF (Radio Frequency) bias is electrically connected to an internal electrode of the holding table 34 via a matching unit 59. The high-frequency power supply 59 can output predetermined power (bias power) having a high frequency of, for example, 13.56 MHz. The matching unit 59 accommodates a matching device which takes matching between impedance of the high-frequency power supply 58 and impedance of loads such as mainly electrodes, plasma and the processing container 32 and contains a blocking capacitor for bias generation. In plasma doping, a bias voltage may or not be supplied to the holding table 34 as necessary.

The holding table 34 can hold the substrate to be processed W using an electrostatic chuck (not illustrated). In addition, the holding table 34 includes a heater (not illustrated) for heating so that the holding table 34 can be set to a desired temperature by means of a temperature adjusting mechanism 29 installed within the holding table 34. The holding table 34 is supported to an insulating tube-like supporter 51 extending upward from the bottom portion 41. The exhaust hole 43 is formed to penetrate through the bottom portion 41 of the processing container 32 along the circumference of the tube-like supporter 51. An exhauster (not illustrated) is connected to the lower side of the annular exhaust hole 43 via an exhaust pipe (not illustrated). The exhauster has a vacuum pump such as a turbo molecular pump or the like. The exhauster allows the pressure in the processing container 32 to be reduced to a predetermined pressure. The control unit 28 serves as a pressure adjusting mechanism which adjusts the pressure in the processing container 32 through exhaust control by the exhauster.

The plasma generating mechanism 39 includes a microwave generator 35 which is installed outside the processing container 32 and generates a microwave for plasma excitation. The plasma generating mechanism 39 also includes the dielectric window 36 which is placed to face the holding table 34 and introduce the microwave generated by the microwave generator 35 into the processing container 32. The plasma generating mechanism 39 also includes a slot antenna plate 37 which is formed with a plurality of slot holes 40 and is disposed above the dielectric window 36 and ejects a microwave to the dielectric window 36. The plasma generating mechanism 39 also includes a dielectric member 38 which is disposed above the slot antenna plate 37 and radially propagates a microwave introduced by a coaxial wave guide 56 (will be described later).

The microwave generator 35 with matching 53 is connected to the upper side of the coaxial wave guide 56 introducing the microwave, via a mode converter 54 and a wave guide 55. For example, a TE mode microwave generated in the microwave generator 35 passes through the wave guide 55, converted to a TEM mode by the mode converter 54 and propagates through the coaxial wave guide 56. A frequency of the microwave generated in the microwave generator 35 may be 2.45 GHz in this example.

The dielectric window 36 has substantially a disc shape and is made of dielectric. A portion of the bottom 48 of the dielectric window 36 is formed with an annular concave portion 57 tapered to facilitate generation of a standing wave by the introduced microwave. The concave portion 57 allows plasma by the microwave to be efficiently generated below the dielectric window 36. The dielectric window 36 may be made of, for example, quartz, alumina or the like.

The slot antenna plate 37 has a thin disc shape. For the plurality of slot holes 40, as illustrated in FIG. 3, a plurality of pairs of two slot holes 40 perpendicular to each other with a predetermined is formed in the circumferential direction at predetermined intervals. In addition, a plurality of pairs of slot holes 40 is formed in the radial direction at predetermined intervals.

The microwave generated by the microwave generator 35 is propagated to the dielectric member 38 through the coaxial wave guide 56. The microwave is radially spread inside the dielectric member 38 interposed between the slot antenna plate 37 and a cooling jacket 52 which contains a circulation path 60 for circulating a refrigerant or the like and adjusts temperature of the dielectric member 30 and so on, and is emitted from the plurality of slot holes 40 formed in the slot antenna plate 37 to the dielectric window 36. The microwave transmitting through the dielectric window 36 produces an electric field right below the dielectric window 36, thereby generating plasma in the processing container 32.

When the microwave plasma is generated in the plasma doping apparatus 31, a so-called plasma generation region having a plasma electron temperature is formed in a region located right below the bottom 48 of the dielectric window 36, particularly below the bottom 48 of the dielectric window 36 by about several centimeters. In addition, a so-called plasma diffusion region where the plasma generated in the plasma generation region is diffused is formed below the plasma generation region. The plasma diffusion region is a region having a relatively low plasma electron temperature in which plasma processing or plasma doping is performed. Thus, without doing so-called plasma damage to the substrate to be processed W in the plasma doping, it is possible to achieve efficient plasma doping, such as reducing doping time, due to high plasma electron density.

Next, a method of performing a plasma doping on the substrate to be processed W using the above-configured plasma doping apparatus will be described. FIG. 4 is a flow chart schematically illustrating a plasma doping method according to one exemplary embodiment of the present disclosure.

Referring to FIG. 4, first, a substrate to be processed W is carried in the processing chamber (Step A) and is held on the holding table. Next, the pressure in the processing container is set to be equal to or more than 100 mTorr and less than 500 mTorr by adjustment of the pressure adjusting mechanism by the control unit (Step B). Thereafter, a doping gas is supplied into the processing container and plasma processing or plasma doping is performed (Step C). Subsequently, the substrate to be processed W is subjected to an annealing (so-called heat treatment) as necessary, and then carried out of the processing container (Step D).

Thus, the plasma doping is performed on the substrate to be processed W. In other words, the plasma doping apparatus according to one exemplary embodiment of the present disclosure is configured to include the control unit for controlling the pressure adjusting mechanism to set the pressure in the processing container to be equal to or more than 100 mTorr and less than 500 mTorr such that the plasma processing is performed on the substrate to be processed W using the plasma generated by the plasma generating mechanism.

With this configuration, plasma is generated by the plasma generating mechanism using a microwave and the pressure in the processing container is set to be equal to or more than 100 mTorr and less than 500 mTorr, thereby performing the plasma processing on the substrate to be processed. Accordingly, as a doping object, the substrate to be processed can be subjected to plasma doping with high conformality while preventing plasma damage.

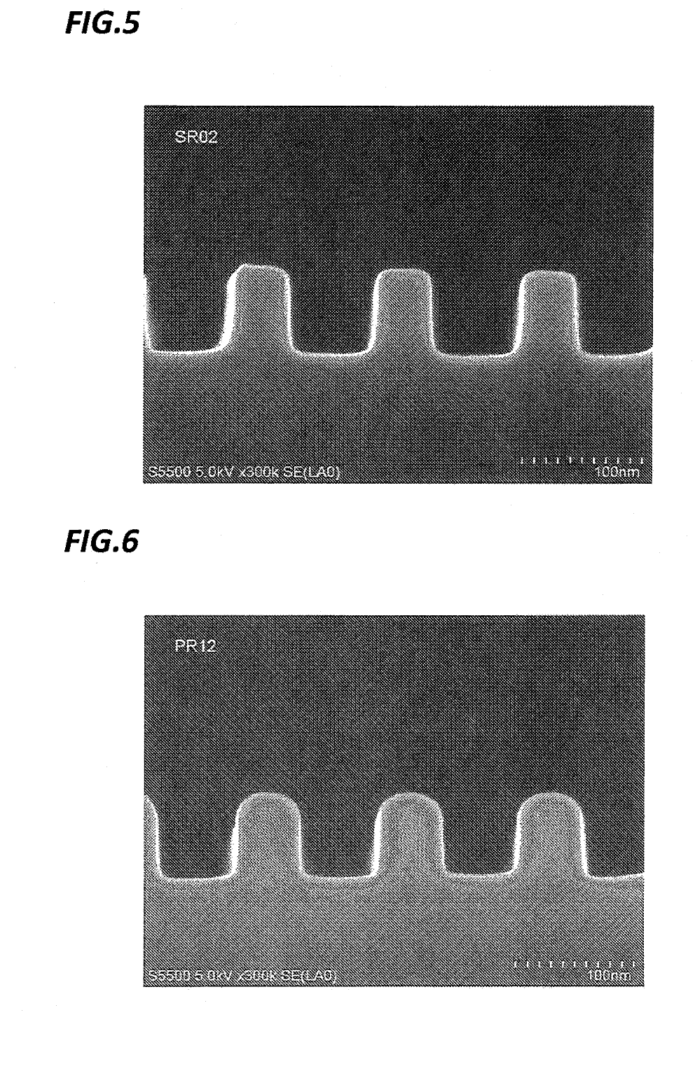

FIG. 5 is an electron micrograph showing a magnified portion of a FinFET type semiconductor device when the pressure in the processing container is set to 200 mTorr. FIG. 6 is an electron micrograph illustrating a magnified portion of a FinFET type semiconductor device when the pressure in the processing container is set to 750 mTorr. The illustrations of FIGS. 5 and 6 have the same process conditions except the pressure in the processing container. More specifically, it is assumed that microwave power is 3 kW, RF bias power is 450 W, a flow rate of supplied mixture of PH₃ and He with a percentage of PH₃ in total set to 0.7% is 28 sccm, and a flow rate of He gas is 972 sccm. The temperature of the holding table may be set to, for example, equal to or less than 200° C.

Referring to FIG. 5, when the pressure in the processing container is set to 200 mTorr, since a shoulder portion of the fin remains at substantially the right angle, it can be understood that any damage (erosion here) does not occur. In contrast, referring to FIG. 6, when the pressure in the processing container is set to 750 mTorr, since the shoulder portion of the fin is cut, it can be understood that any erosion occurs. On the other hand, even when the pressure in the processing container is set to be equal to or less than 100 mTorr, since the fin has a shape as illustrated in FIG. 6, any erosion occurs.

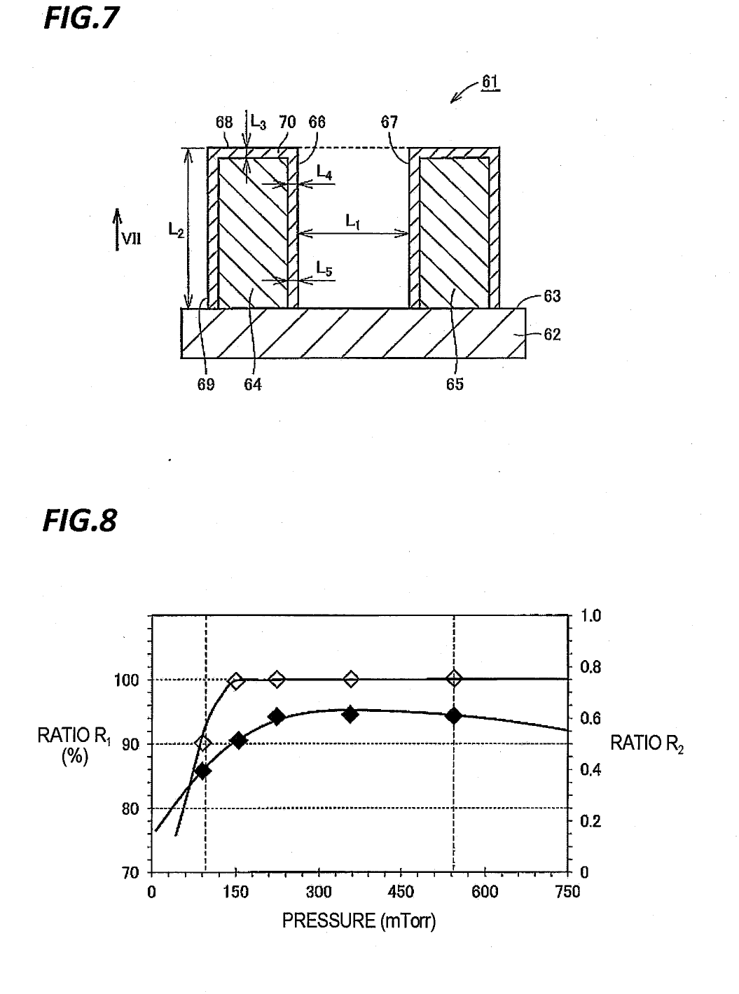

FIG. 7 is a sectional view illustrating a portion of the section of a FinFET type semiconductor device 61. The section illustrated in FIG. 7 corresponds to the figure viewed in the direction of arrow I in FIG. 1. Referring to FIG. 7, in the FinFET type semiconductor device 61, a first fin 64 and a second fin 65 are formed to extend upward from a surface 63 of a silicon substrate 62, i.e., in a direction of arrow VII in FIG. 7. A distance between the adjacent first fin 64 and second fin 65 formed on the silicon substrate 62, i.e., a length L₁ in the horizontal direction from a side wall 66 of the first fin 64 which is located at the side of the second fin 65 to a side wall 67 of the second fin 65 which is located at the side of the first fin 64, is set to 90 nm. In addition, a height of the first fin 64, i.e., a length L₂ from the surface 63 of the silicon substrate 62 to an upper wall 68 of the first fin 64 which extends upward, is set to 75 nm. On the other hand, a height of the second fin 65 is set to be approximately equal to the height of the first fin 64.

Doping is performed in such a manner to inject dopants into a surface of the fin 64, i.e., the upper wall 68 and both side walls 66 and 69 thereof, up to a predetermined doping depth. The same is true of the fin 65. In this case, to achieve conformal doping, the doping depth for the upper wall 68, the doping depth for an upper side of the side wall 66 and the doping depth for a lower side of the side wall 66 are equal to each other as possible. In FIG. 7, a doped region of the upper wall 68 and the side walls 66 and 69 of the fin 64 is denoted by reference numeral 70. The doping depth for the upper wall 68 is indicated by a length L₃ in FIG. 7, the doping depth for the upper side of the side wall 66 is indicated by a length L₄ in FIG. 7, and the doping depth for the lower side of the side wall 66 is indicated by a length L₅ in FIG. 7. A portion indicated by the length L₄ corresponds to a position spaced by 70 nm from the surface 63 of the silicon substrate 62 and a portion indicated by the length L₅ corresponds to a position spaced by 5 nm from the surface 63 of the silicon substrate 62.

FIG. 8 is a graph illustrating plasma doping depth ratios. The left vertical axis represents a ratio of the doping depth for the lower side wall 66 corresponding to the length L₅ to the doping depth for the upper wall 68 corresponding to the length L₃ by percentage (%). The right vertical axis represents a ratio of the doping depth for the lower side wall 66 corresponding to the length L₅ to the doping depth for the upper side wall 66 corresponding to the length L₄. The horizontal axis represents the internal pressure (mTorr) of the processing container, which increases toward the right side of the graph. White diamonds in FIG. 8 indicate a ratio of the doping depth for the lower side wall 66 corresponding to the length L₅ to the doping depth for the upper wall 68 corresponding to the length L₃. This ratio is hereinafter referred to as ratio R₁. Black diamonds in FIG. 8 indicate a ratio of the doping depth for the lower side wall 66 corresponding to the length L₅ to the doping depth for the upper side wall 66 corresponding to the length L₄. This ratio is hereinafter referred to as ratio R₂. A ratio R₁ closer to 100 provides better conformality. A ratio R₂ closer to 0 provides better conformality.

Referring to FIG. 8, the ratio R₁ is about 90% when the pressure in the processing container is 100 mTorr. When the pressure in the processing container increases over 100 mTorr, the ratio R₁ approaches to 100%. The ration R₁ becomes about 100% when the pressure in the processing container is 150 mTorr. The ration R₁ remains at about 100% when the pressure in the processing container increases above 150 mTorr.

The ratio R₂ is about 0.4 when the pressure in the processing container is 100 mTorr. When the pressure in the processing container increases above 100 mTorr, the ratio R₂ also increases and becomes about 0.6 between 200 mTorr and 500 mTorr.

When the pressure in the processing container is less than 100 mTorr, both of the ratios R₁ and R₂ tend to decrease, i.e., grow apart from 100 and 1, respectively, as illustrated in FIG. 8. When the pressure in the processing container is equal to or more than 500 mTorr, the ratio R₁ tends to be substantially unchanged but the ratio R₂ tends to decrease.

Regarding the ratio R₂, when the pressure in the processing container is less than 450 mTorr, the ratio R₁ comes close to 100 and the ratio R₂ approaches 1, resulting in relatively high values. When the pressure in the processing container is equal to or less than 150 mTorr and equal to or less than 250 mTorr, the ratios R₁ and R₂ can be securely close to 100 and 1, respectively.

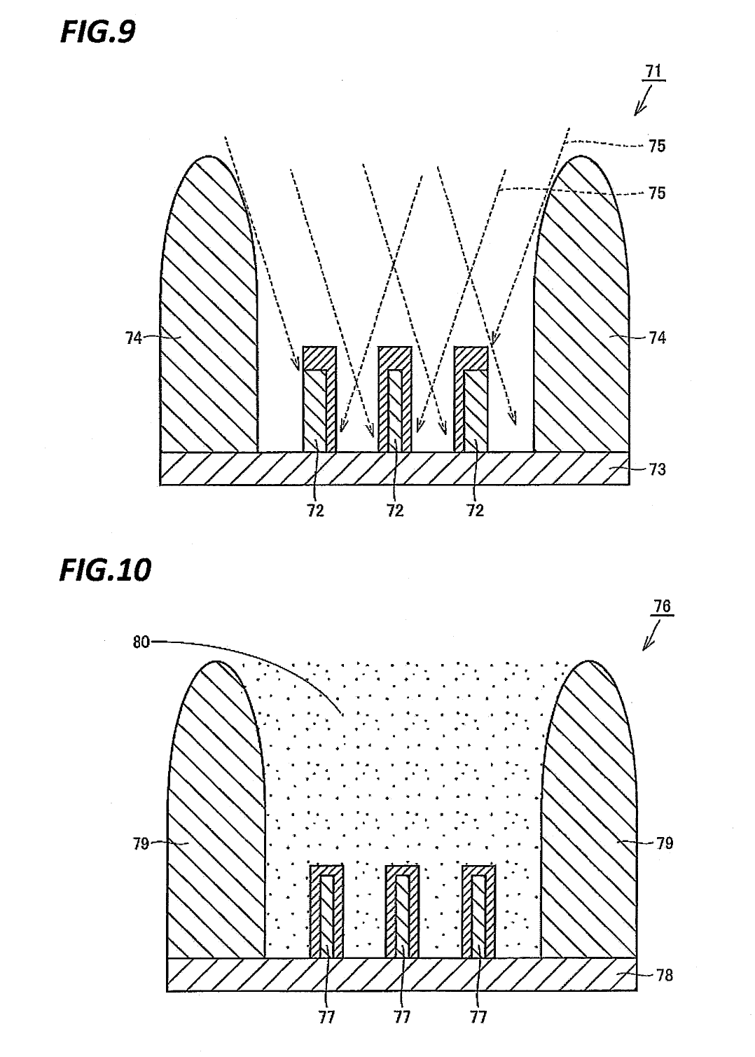

Doping performed using an ion injection apparatus will now be described. FIG. 9 is a schematic view illustrating a case where an ion injection apparatus is used to perform a doping on a fin 72 of a FinFET type semiconductor device 71. On the other hand, FIG. 10 is a schematic view illustrating a case where the above-configured plasma doping apparatus is used to perform a plasma doping. First, referring to FIG. 9, a photoresist layer 74 formed on a silicon substrate 73 is relatively higher than the fin 72. In this case, ion injection in the doping using the ion injection apparatus has anisotropy. Therefore, a region of a side wall of the fin 72, particularly a lower region of the side wall, shadows the higher photoresist layer 74, thereby preventing proper injection of ions emitted in an oblique direction indicated by dotted lines 75 in FIG. 9. That is, particularly for the fin 72 disposed near the photoresist layer 74, ions are insufficiently injected into the photoresist layer 74.

In contrast, referring to FIG. 10, in the doping using plasma generated by a microwave, irrespective of a height of a photoresist layer 79 formed on a silicon substrate 78 of a FinFET type semiconductor device 76, a region where a fin 77 is formed is placed in a so-called plasma diffusion region 80. In addition, irrespective of the height of the photoresist layer 79, the entire surface of the fin 77 is subjected to isotropic plasma doping in the plasma diffusion region 80. This can result in conformal doping for the FinFET type semiconductor device 76.

As can be seen from the above description, according to the above-configured plasma doping apparatus and plasma doping method, it is possible to provide plasma doping with high conformality for a substrate to be processed, which is a doping object, while preventing damage (erosion) to the substrate.

A method of manufacturing a semiconductor device according to one exemplary embodiment of the present disclosure involves manufacturing a semiconductor device by injecting dopants into a substrate to be processed. The semiconductor device manufacturing method includes steps of holding a substrate to be processed on a holding table disposed in a processing container, supplying a doping gas and an inert gas for plasma excitation into the processing container, generating plasma in the processing container using a microwave, and setting a pressure in the processing container to be equal to or more than 100 mTorr and less than 500 mTorr, thereby performing a plasma processing on the substrate to be processed.

A semiconductor device according to one exemplary embodiment of the present disclosure is manufactured by injecting dopants into a substrate to be processed. The semiconductor device is manufactured through steps of holding a substrate to be processed on a holding table disposed in a processing container, supplying a doping gas and an inert gas for plasma excitation into the processing container, generating plasma in the processing container using a microwave, and setting a pressure in the processing container to be equal to or more than 100 mTorr and less than 500 mTorr, thereby performing a plasma processing on the substrate to be processed.

Meanwhile, after the above-described plasma processing is performed on the substrate to be processed W, the pressure in the processing container may be controlled to be lower than the pressure set when the plasma processing is performed on the substrate to be processed such that another plasma processing is performed on the substrate to be processed using the generated plasma.

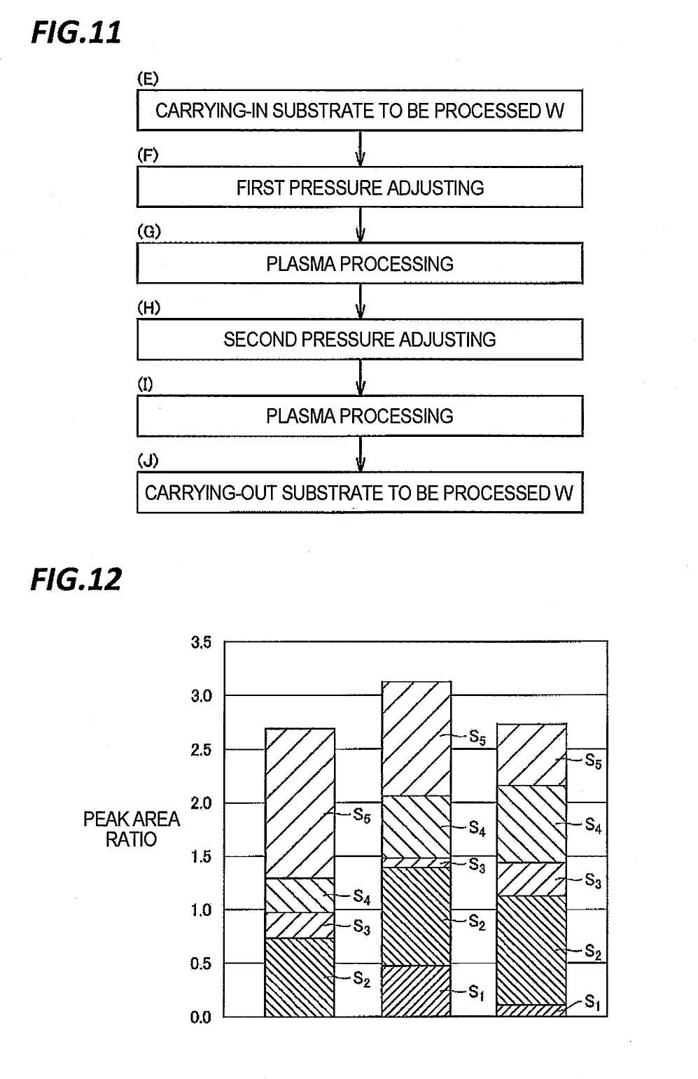

FIG. 11 is a flow chart schematically illustrating a plasma doping method in this case. Referring to FIG. 11, in a plasma doping method according to another exemplary embodiment of the present disclosure, a substrate to be processed W is first carried in the processing container (Step E) and is held on the holding table. Next, the pressure in the processing container is set to be equal to or more than 100 mTorr and less than 500 mTorr (Step F). This step is referred to as a first pressure adjusting step. Thereafter, plasma processing using microwave plasma, i.e., plasma doping, is performed (Step G). Next, after completing the plasma doping, the pressure in the processing container is adjusted to a pressure lower than the pressure set when the plasma processing is performed (Step H). This step is referred to as a second pressure adjusting step. Thereafter, additional plasma processing is performed (Step I). Subsequently, the substrate to be processed W is subjected to an annealing (so-called heat treatment) as necessary, and then carried out of the processing container (Step J).

With this configuration, it is possible to suppress dopants injected by doping from being separated from the substrate to be processed W subjected to the first plasma processing. That is, it is possible to suppress dopants from being separated from the substrate to be processed W subjected to the doping due to elution of the dopants by a cleaning processing using chemicals performed after the doping.

In this connection, the amount of dose measured after a substrate to be processed which was not subjected to the second plasma processing with the pressure in the processing container set to a low pressure was carried out of the processing container was 1.78E+15 (atoms/cm²). The measurement was made by making analysis by SIMS (Secondary Ion Mass Spectrometer) and taking a profile of P (phosphorus) in the depth direction from a surface of a Si (silicon) substrate. Process conditions for plasma doping were as follows: microwave power: 3 kW, RF bias power: 450 W, flow rate of supplied mixture of PH₃ and He with a percentage of PH₃ in total set to 0.7%:28 sccm, flow rate of He gas: 972 sccm, doping time: 40 seconds, and the pressure in the processing container: 150 mTorr. The substrate to be processed which was not subjected to the second plasma processing was immersed in DHF (Diluted Hydrofluoric Acid having 0.5% concentration) for 20 seconds. The amount of dose measured again in the same manner thereafter was 1.65E+14 (atoms/cm²). That is, the amount of dose was reduced by about 90.7%.

In contrast, as illustrated in FIG. 11, the amount of dose measured after a substrate to be processed which was subjected to the second plasma processing with the pressure in the processing container set to a low pressure was carried out of the processing container was 1.98E+15 (atoms/cm²). Process conditions for plasma doping were as follows: microwave power: 3 kW, RF bias power: 450 W, flow rate of supplied mixture of PH₃ and He with a percentage of PH₃ in total set to 0.7%:28 sccm, flow rate of He gas: 972 sccm, doping time: 40 seconds, and the pressure in the processing container: 150 mTorr. Then, the substrate to be processed W was subjected to the second plasma processing using microwave plasma generated by controlling the pressure in the processing container to a second pressure, i.e., a pressure lower than the pressure set when the substrate to be processed W was subjected to the doping. Process conditions for the plasma processing were as follows: microwave power: 3 kW, RF bias power: 450 W, flow rate of supplied mixture of PH₃ and He with a percentage of PH₃ in total set to 0.7%:14 sccm, flow rate of He gas: 972 sccm, plasma processing time: 20 seconds, and the pressure in the processing container: 75 mTorr.

The substrate to be processed which was subjected to the second plasma processing was immersed in DHF for 20 seconds, as in the case where the substrate to be processed was not subjected to the second plasma processing. The amount of dose measured again thereafter was 1.39E+15 (atoms/cm²). That is, the amount of dose was reduced by about 29.8%.

In this manner, after the plasma processing is performed on the substrate to be processed, the pressure in the processing container is controlled to be set to a pressure lower than the pressure set when the plasma processing is performed on the substrate to be processed such that another plasma processing is performed on the substrate to be processed using the generated plasma. This can result in prevention of separation of dopants injected by the doping. In addition, separation of the injected dopants in a cleaning processing may be prevented by annealing such as high temperature heat treatment. However, if annealing after the doping cannot be performed or annealing time is intended to be as short as possible depending on process conditions, the above-described configuration illustrated in FIG. 11 may be employed. Here, in the above case, the pressure in the processing container set when the plasma processing is performed may be lower than 150 mTorr or even 100 mTorr. In addition, the gas supplied for the second plasma processing may not contain PH₃.

FIG. 12 is a graph (results of analysis by XPS) showing waveform components of 2p3/2 spectrum of Si (silicon) when a cleaning processing was performed on a substrate to be processed using DHF. For the XPS analysis, AlKα (1486.6 eV) was used as an X ray source and a photoelectron escape angle (or TOA (Time Of Arrival)) was set to 50°. The Si 2p3/2 spectrum is obtained by subtracting a spin orbit 1/2 component from a Si2p spectrum. In FIG. 12, the left bar graph represents a substrate to be processed which is not subjected to the second plasma processing, the middle bar graph represents a substrate to be processed which is subjected to the second plasma processing, and the right bar graph represents a substrate to be processed which is subjected to the second plasma processing and then the cleaning processing with DHF. In FIG. 12, a region S₁ represents a peak of Si—H bond, a region S₂ represents a peak of Si¹⁺ orbit, a region S₃ represents a peak of Si²⁺ orbit, a region S₄ represents a peak of Si³⁺ orbit, and a region S₅ represents a peak of Si⁴⁺ orbit. It is considered that Si¹⁺, Si²⁺, Si³⁺ and Si⁴⁺ indicate the existence of Si₃—Si—O, Si₂—Si—O₂, Si—Si—O₃ and O₂—Si—O₂, respectively. It is guessed that the existence of oxygen results from a natural oxide film.

Referring to FIG. 12, when the second plasma processing is not performed, the region S₁ does not appear although the regions S₂ to S₅ exist, which means the exclusion of Si—H bond. In contrast, when the second plasma processing is performed, all of the regions S₁ to S₅ appear, which means the inclusion of Si—H bond. When the DHF cleaning processing is performed after the second plasma processing, an area of peak of the Si—H bond appearing in the region S₁ decreases. Then, it is considered that the existence of Si—H bond has contribution to prevention of separation of dopants.

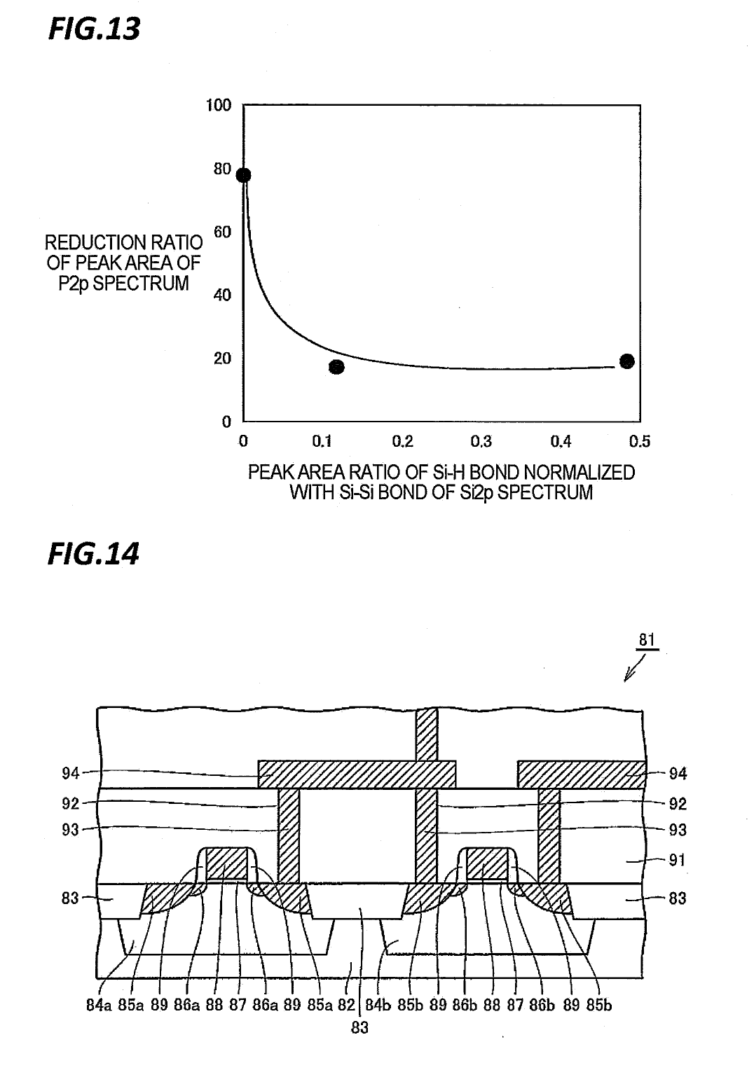

FIG. 13 is a graph showing a relationship between a reduction rate of a peak area of a P (phosphorus) 2p spectrum and a peak area ratio of Si—H bond normalized with Si—Si bond of a Si (silicon) 2p spectrum. The vertical axis represents the reduction rate of the peak area of the P 2p spectrum and the horizontal axis represents the peak area ratio of Si—H bond normalized with Si—Si bond of the Si 2p spectrum.

Referring to FIG. 13, when a value obtained by normalizing the peak area of Si—H bond of the silicon 2p spectrum with a silicon substrate peak area is 0, the reduction rate of peak are of the P 2p spectrum is a high value of 80%. This value means that the separation of injected dopants is relatively high. In contrast, when the value obtained by normalizing the peak area of Si—H bond of the silicon 2p spectrum with the silicon substrate peak area is equal to or more than 0.1, the reduction rate of peak are of the P 2p spectrum can be limited to about 20%. This value means that the separation of injected dopants is relatively low. Therefore, the value obtained by normalizing the peak area of Si—H bond of the silicon 2p spectrum with the silicon substrate peak area may be set to be equal to or more than 0.1.

That is, a semiconductor device according to another exemplary embodiment of the present disclosure may have a value of 0.1 or more obtained by normalizing the peak area of Si—H bond of the silicon 2p spectrum with the silicon substrate peak area.

Although it has been illustrated in the above exemplary embodiments that a PH₃-containing gas is used as the doping gas, without being limited thereto, the doping gas may be at least one selected from a group consisting of B₂H₆, PH₃, AsH₃, GeH₄, CH₄, NH₃, NF₃, N₂, HF and SiH₄. That is, arsenic (As) or carbon (C) may be effectively used for doping.

In addition, although it has been illustrated in the above exemplary embodiments that He is used as the inert gas for plasma excitation, without being limited thereto, the inert gas may be at least one selected from a group consisting of He, Ne, Ar, Kr and Xe.

In addition, although it has been illustrated in the above exemplary embodiments that a FinFET type semiconductor device is used as the semiconductor device, without being limited thereto, the present disclosure may be applied to a MOS type semiconductor device. FIG. 14 is a schematic sectional view illustrating a portion of a MOS type semiconductor device according to still another exemplary embodiment of the present disclosure. In the MOS type semiconductor device illustrated in FIG. 14, a conductive layer is indicated by hatching.

Referring to FIG. 14, a MOS type semiconductor device 81 includes a silicon substrate 82 formed thereon with element isolation regions 83, a p-type well 84a, an n-type well 84b, high concentration n-type impurity diffusion regions 85a, high concentration p-type impurity diffusion regions 85b, n-type impurity diffusion regions 86a, p-type impurity diffusion regions 86b and gate oxide films 87. One of the high concentration n-type impurity diffusion regions 85a with one gate oxide film 87 interposed therebetween and one of the high concentration p-type impurity diffusion regions 85b with another gate oxide film 87 interposed therebetween correspond to a drain and the others correspond to a source.

A gate electrode 88 serving as a conductive layer is formed on each gate oxide film 87 and a gate side wall 89 serving as an insulating film is formed on a side of the gate electrode 88. Further, an insulating film 91 is formed on the silicon substrate 82 on which the gate electrodes 88 and so on are formed. Contact holes 92 are formed in the insulating film 91, with the contact holes 92 connected to the high concentration n-type impurity diffusion regions 85a and the high concentration p-type impurity diffusion regions 85b, and hole filling electrodes 93 are formed in the contact holes 92. In addition, metal wiring layers 94 serving as conductive layers are formed thereon. Further, interlayer insulating films (not illustrated) serving as insulating layers and metal wiring layers serving as conductive layers are alternately formed and pads (not illustrated) serving as contact points with the outside are finally formed. Thus, the MOS type semiconductor device 81 is completed.

The MOS type semiconductor device 81 according to another exemplary embodiment of the present disclosure is formed by subjecting the n-type impurity diffusion regions 86a and the p-type impurity diffusion regions 86b to doping using the above-described plasma doping apparatus. More specifically, for example, for the n-type impurity diffusion regions 86a, a B₂H₆ gas is used as a doping gas and boron (B) is injected as dopants. These regions 86a require extremely shallow junction, low junction breakdown voltage and low junction leak. Here, the plasma doping by the above-described configuration can reduce damage to the substrate to be processed and achieve high conformality.

Next, a case where arsenic (As) is injected as dopants for plasma doping performed using the above-described doping apparatus 31 will be described. In more detail for the configuration of the above-described plasma doping apparatus 31, the first gas supplying part 46 included in the plasma doping apparatus 31 is formed with one gas supplying hole 30, whereas the second gas supplying part 47 is formed with 24 gas supplying holes 50. The 24 gas supplying holes 50 are formed at the same intervals in the circumferential direction. In the specification, a gas supplied from the gas supplying hole 30 may be sometimes referred to as a center gas and a gas supplied from the plurality of gas supplying holes 50 may be sometimes referred to as an edge gas. It is here assumed that the center gas and the edge gas have the same gas composition.

After the doping, heat treatment such as lamp annealing is performed. Then, dopants injected into the silicon substrate are activated to decrease surface resistance of the silicon substrate, i.e., so-called sheet resistance of a substrate to be processed. Thus, electric characteristics of the silicon substrate are improved. On the other hand, the sheet resistance requires homogeneity, i.e., high in-plane uniformity, over the entire surface of the substrate to be processed.

Doping of arsenic (As) into the silicon substrate is now considered. When As is injected as dopants, for example, a AsH₃-containing dopant gas is used. It is common that sheet resistance after annealing decreases with increase in the amount of dose injected by doping, i.e., the number of injected atoms. However, when As is used as dopants, the sheet resistance decreases with increase in As up to a certain amount, whereas it increases beyond the certain amount of As. Such inversion of the sheet resistance appears noticeably when As is used as dopants.

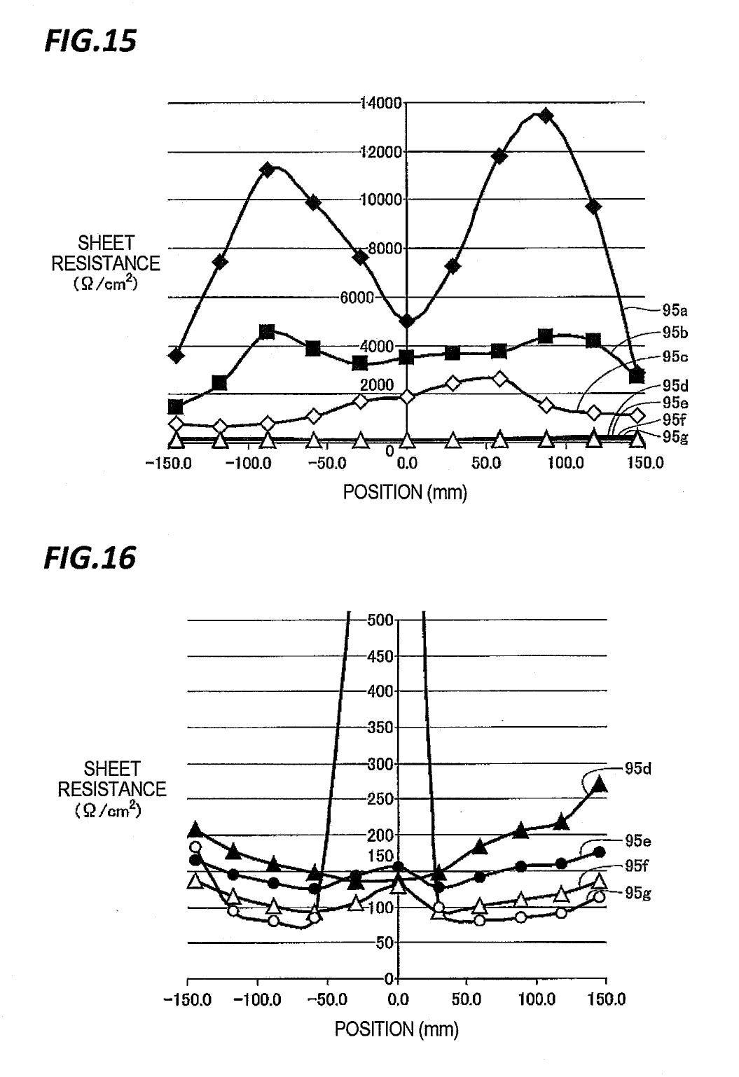

This will be described below in more detail. FIGS. 15 and 16 are graphs showing a relationship between a position and a sheet resistance of a substrate to be processed W when a flow rate of doping gas is changed. In FIGS. 15 and 16, the vertical axis represents sheet resistance (Ω/cm²) and the horizontal axis represents position (mm) in the substrate to be processed W. A numeric value 0 in the center of the horizontal axis indicates the center of a disc-like substrate to be processed and moving away to the left and right of the horizontal axis means approaching to an edge of the disc-like substrate to be processed W. As this case employs a substrate to be processed which has a diameter of 300 mm, the horizontal axis shows a range of −150 mm to +150 mm. FIG. 15 having a wider range of vertical axis shows a range of 0 to 14000 /cm² and FIG. 16 having a narrower range of vertical axis shows a range of 0 to 500 Ω/cm².

In FIGS. 15 and 16, black diamonds and a solid line 95a are for a doping gas flow rate of 14 sccm (standard cc/min), black squares and a solid line 95b are for a doping gas flow rate of 24 sccm, white diamonds and a solid line 95c are for a doping gas flow rate of 34 sccm, black triangles and a solid line 95d are for a doping gas flow rate of 49 sccm, black circles and a solid line 95e are for a doping gas flow rate of 61 sccm, white triangles and a solid line 95f are for a doping gas flow rate of 73 sccm, and white circles and a solid line 95g are for a doping gas flow rate of 98 sccm. It is here noted that only one of the graphs has detailed indications.

Here, an AsH₃/He mixture gas diluted with He is used as the doping gas. Specifically, a mixture gas having a flow ratio of AsH₃/He=61/939 is diluted with He and is flown into the processing container 31 at a total of flow rate of 1000 sccm from the gas supplying unit 33. That is, the doping gas of 14 sccm means that it has a ratio of AsH₃/He:He is 14 sccm:986 sccm.

Other process conditions for this case are as follows: microwave power: 3 kW, bias power: 450 W, the pressure in the processing container 32: 150 mTorr, processing time: 40 seconds, a flow ratio of center gas to edge gas: 20/80, and a distance from the bottom 48 of the dielectric window 36 to the top side of the holding table 34: 135 mm. In addition, lamp annealing after the doping is performed at 1050° C. for 120 seconds. Measurement on sheet resistance is made using a 4-probe measuring device.

First, referring to FIG. 15 showing a wider range of vertical axis, when the flow rate of doping gas is 14 sccm, the center and edge of the substrate to be processed W tend to be significantly different in sheet resistance from each other. As a whole, the sheet resistance tends to decrease with increase in the flow rate of doping gas. However, referring to FIG. 16 showing a narrower range of vertical axis, this effect is reversed in, particularly the center of the substrate to be processed W. More specifically, in comparison with the doping gas flow rate of 49 sccm, the doping gas flow rate of 61 sccm provides sheet resistance increasing over a range of −25 mm to +25 mm. This tendency becomes more noticeable with increase in the flow rate of doping gas. For the doping gas flow rate of 98 sccm, the sheet resistance increases over a range of −50 mm to +50 mm.

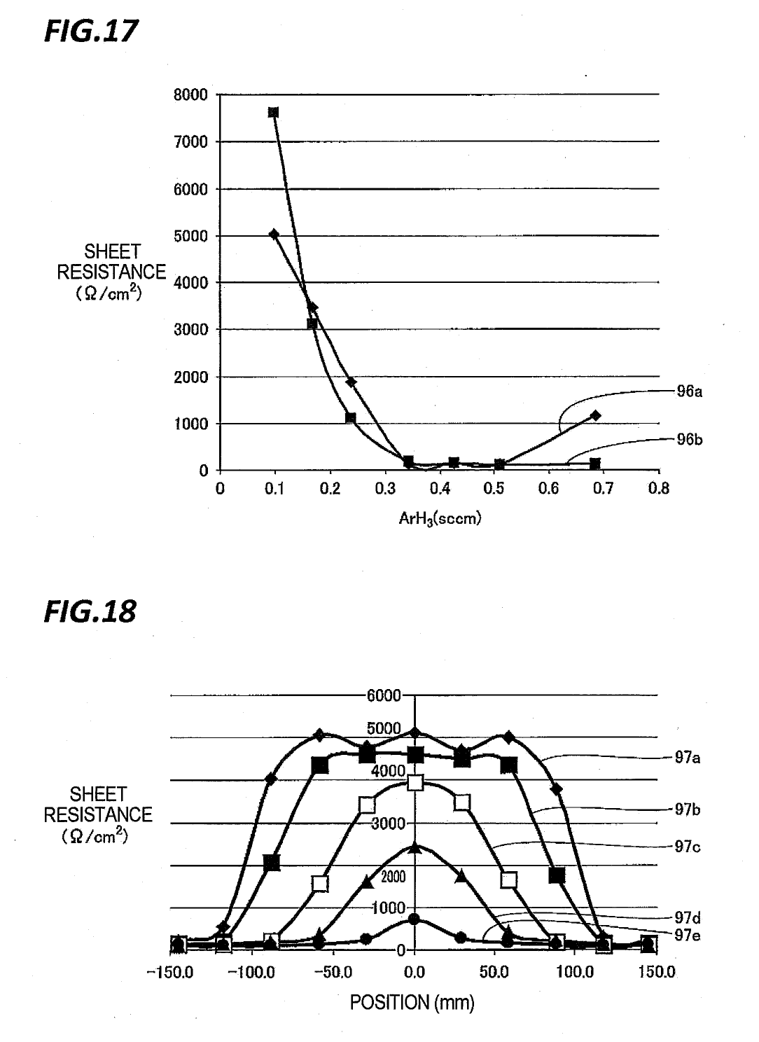

This effect can be understood from FIG. 17 showing a relationship between a flow rate of AsH3 in the doping gas and a sheet resistance. In FIG. 17, the vertical axis represents sheet resistance (Ω/cm²) and the horizontal axis represents a flow rate (sccm) of AsH₃. In FIG. 17, black diamonds and a solid line 96a indicate measurements at the central position of a substrate to be processed W and black squares and a solid line 96b indicate an average of measurements at different positions of the substrate to be processed W. Referring to FIG. 17, the average of the sheet resistances tends to decrease with increase in the flow rate of AsH₃. However, in the central position of the substrate to be processed W, with increase in the flow rate of AsH₃, the average of the sheet resistances tends to decrease until the flow rate of AsH₃ reaches about 0.35 sccm, whereas it increases after the flow rate of AsH₃ reaches about 0.5 sccm.

This effect may envisage the following aspects. Ar atoms are injected into a substrate to be processed, which is a doping object, for example, a silicon substrate, up to a predetermined amount of dose, and stay alone in the silicon substrate. Then, the Ar atoms are activated by later annealing, which results in contribution to reduction of sheet resistance. However, if the Ar atoms are injected over the predetermined amount dose, the injected Ar atoms are combined and clustered in the silicon substrate. A group of clustered Ar atoms will not be activated even by later annealing. As a result, it is believed that the inactivated group of Ar atoms has no contribution to reduction of sheet resistance but causes increase in the sheet resistance.

This effect is undesirable from the following aspects related to electric characteristics. The first aspect involves deteriorated in-plane uniformity of the substrate to be processed W. More specifically, as shown in the above example, the sheet resistances in the center and edge of the substrate to be processed W are significantly different from each other with increase in the flow rate of doping gas. The second aspect involves difficulty in setting of appropriate process conditions. For example, even when the flow rate of doping gas is increased to achieve increase in the amount of dose aimed at decrease in sheet resistance, there is a possibility of increase in the sheet resistance, as opposed to decrease in the sheet resistance.

From the viewpoint of securing good electric characteristics of a silicon substrate, obtained when As is injected as dopants, there is a need to supply an appropriate amount of doping gas with an aim at minimal sheet resistance. That is, there is a need to supply a doping gas to be injected into the silicon substrate by an appropriate amount of dose, not too much and not too little, with an aim at minimal sheet resistance obtained when As is injected as dopants. In addition, it is desirable to make in-plane uniformity of sheet resistance as high as possible.

Here, the following configuration is employed to provide good electric characteristics when As is injected as dopants. The present inventors have recognized the above-mentioned problems caused when As is injected as dopants and, as a result of careful study on these problems, have paid attention on a flux of As atoms having significant effect on the number of As atoms supplied for doping with these As atoms. As a result, the following relationship was found. If a relationship of 5.0E+13 m⁻²·sec⁻¹<flux F₁ of As atoms supplied in a direction perpendicular to a substrate to be processed<1.0E+14 m⁻²·sec⁻¹ is established, this relationship has been found to result in good electric characteristics and high in-plane uniformity. In other words, it has been found that, when the supplied doping gas contains As atoms whose flux F₁ lies between 5.0E+13 and 1.0E+14 per sec and square, As atoms as many as possible but not clustered can be injected as dopants, which can result in good electric characteristics and high in-plane uniformity.

That is, a plasma doping method according to another exemplary embodiment of the present disclosure is a plasma doping method for performing doping by injecting dopants into a substrate to be processed. In the plasma doping method, a plasma doping is performed on the substrate to be processed by holding the substrate to be processed on the holding table disposed in the processing container, supplying an As-containing doping gas and an inert gas for plasma excitation into the processing container, generating plasma in the processing container using a microwave, and establishing a relationship of 5.0E+13 m⁻²·sec⁻¹<flux F₁ of As atoms supplied in a direction perpendicular to the substrate to be processed<1.0E+14 m⁻²·sec⁻¹ with the pressure in the processing container set to be equal to or more than 100 mTorr and less than 500 mTorr.

Here, the lower limit 5.0E+13 m⁻²·sec⁻¹ is calculated from a result obtained through two-dimensional plasma distribution simulation under process conditions capable of obtaining a required amount of dose (5E+15 atoms/cm²) or more. The upper limit 1.0E+14 m⁻²·sec⁻¹ is calculated from a result obtained through two-dimensional plasma distribution simulation under process conditions capable of obtaining sufficiently low sheet resistance (300 Ω/cm²) without As atoms clustered.

In this case, supplied bias power is preferably set to a range of 250 W to 650 W.

When the pressure in the processing container 32 in the plasma doping is set to a range of 100 mTorr to 150 mTorr, a relationship of 7.0E+13 m⁻²·sec⁻¹<flux F₁ of As atoms supplied in a direction perpendicular to the substrate to be processed<9.0E+13 m⁻²·sec⁻¹ is preferably established.

That is, the plasma processing may be performed on the substrate to be processed by establishing a relationship of 7.0E+13 m⁻²·sec⁻¹<flux F₁ of As atoms supplied in a direction perpendicular to the substrate to be processed<9.0E+13 m⁻²·sec⁻¹ with the pressure in the processing container set to be equal to or more than 100 mTorr and less than 150 mTorr.

FIG. 18 is a graph showing a relationship between a position and a sheet resistance of a substrate to be processed W when a flow ratio of center gas/edge gas is changed. In the figure, the vertical axis represents sheet resistance (Ω/cm²) and the horizontal axis represents position (mm) in the substrate to be processed W. The horizontal axis is the same as those in FIGS. 15 and 16. The vertical axis is also the same as those in FIGS. 15 and 16 except a range of resistance. In FIG. 18, black diamonds and a solid line 97a indicate a flow ratio of center gas/edge gas=70/30, black squares and a solid line 97b indicate a flow ratio of center gas/edge gas=50/50, white squares and a solid line 97c indicate a flow ratio of center gas/edge gas=30/70, black triangles and a solid line 97d indicate a flow ratio of center gas/edge gas=20/80, and black circles and a solid line 97e indicate a flow ratio of center gas/edge gas=10/90.

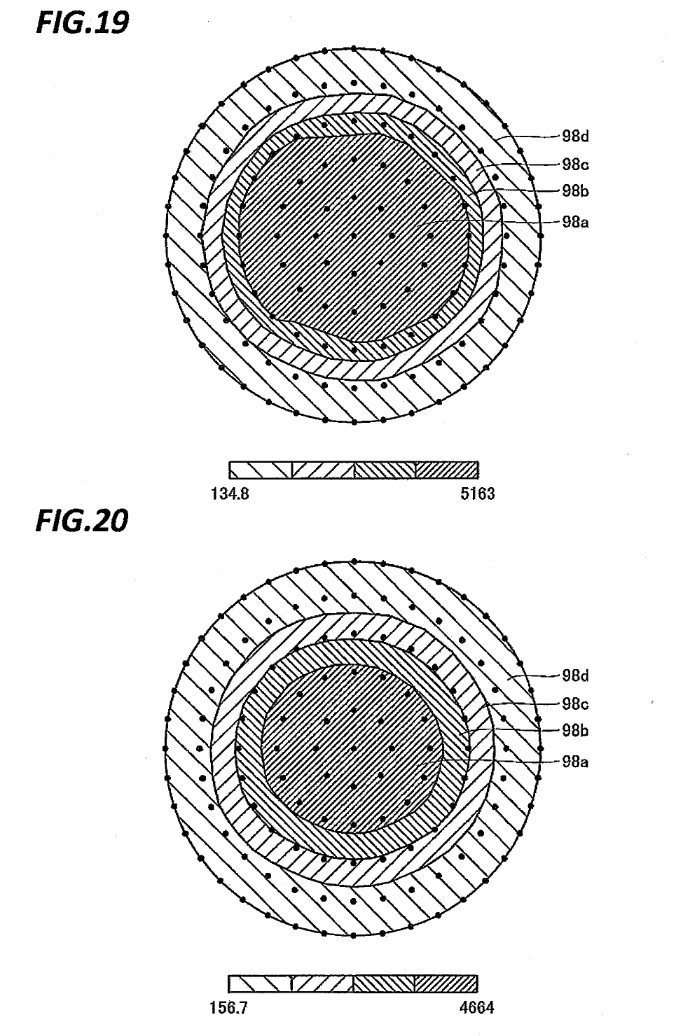

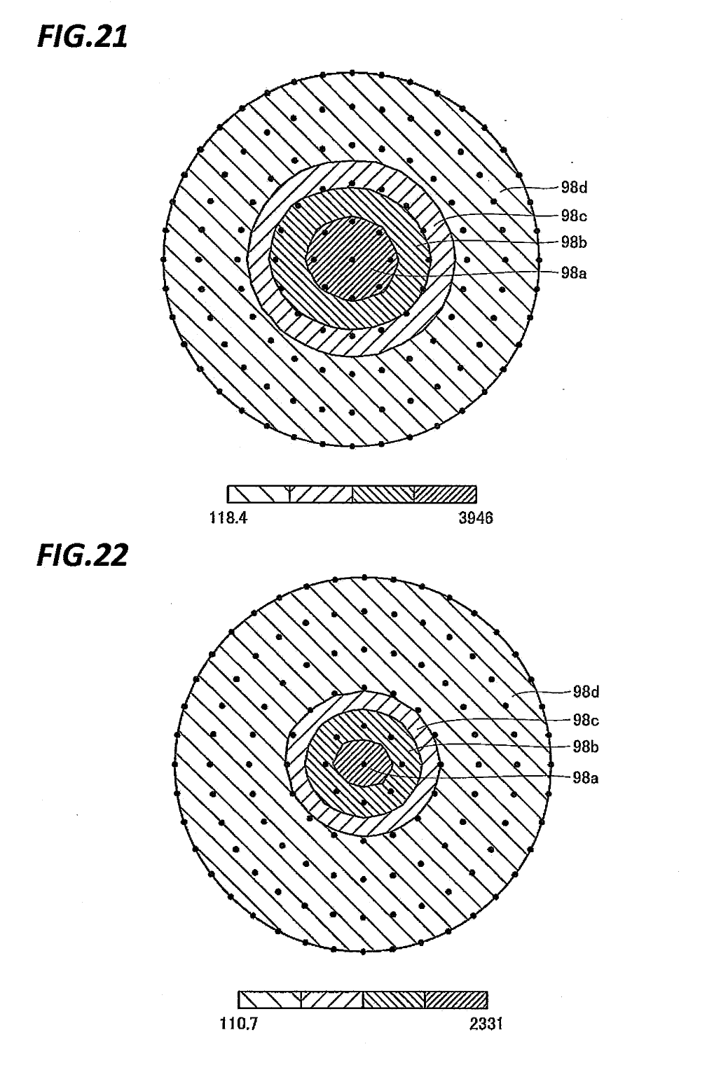

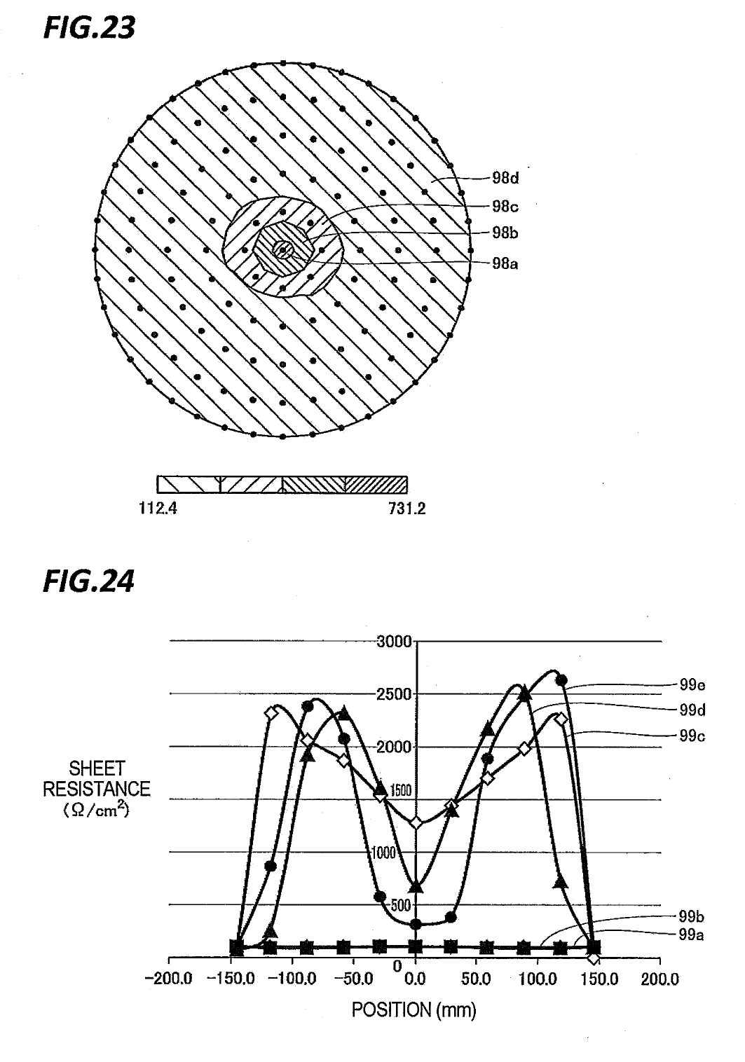

FIG. 19 is a view illustrating a distribution of sheet resistance when a flow ratio of center gas/edge gas=70/30. FIG. 20 is a view illustrating a distribution of sheet resistance when a flow ratio of center gas/edge gas=50/50. FIG. 21 is a view illustrating a distribution of sheet resistance when a flow ratio of center gas/edge gas=30/70. FIG. 22 is a view illustrating a distribution of sheet resistance when a flow ratio of center gas/edge gas=20/80. FIG. 23 is a view illustrating a distribution of sheet resistance when a flow ratio of center gas/edge gas=10/90. Here, the sheet resistance is largely divided into four regions 98a, 98b, 98c and 98d showing higher resistance in this order. Other process conditions and annealing conditions are the same as those in FIGS. 15 and 16. These sheet resistances are obtained by measuring ones obtained through experiments at various dot positions using a 4-probe measuring device (available from Napson Co., Ltd.), extracting a portion of a 2D distribution, and drawing the extracted portion using drawing software such that it has a distribution of four regions.

Referring to FIGS. 18 to 23, it can be understood that a lower percentage of center gas and a higher percentage of edge gas in the flow ratio of center gas/edge gas provide lower sheet resistance and higher in-plane uniformity. That is, good electric characteristics and high in-plane uniformity can be obtained by decreasing the percentage of center gas and increasing the percentage of edge gas so that a flux F₁ of As atoms supplied in a direction perpendicular to the substrate to be processed can fall within a range of 7.0E+13 m⁻²·sec⁻¹ to 9.0E+13 m⁻²·sec⁻¹.

When As is injected as dopants to achieve good electric characteristics and maintain high in-plane uniformity, a small amount of hydrogen may be added as a dilution gas.

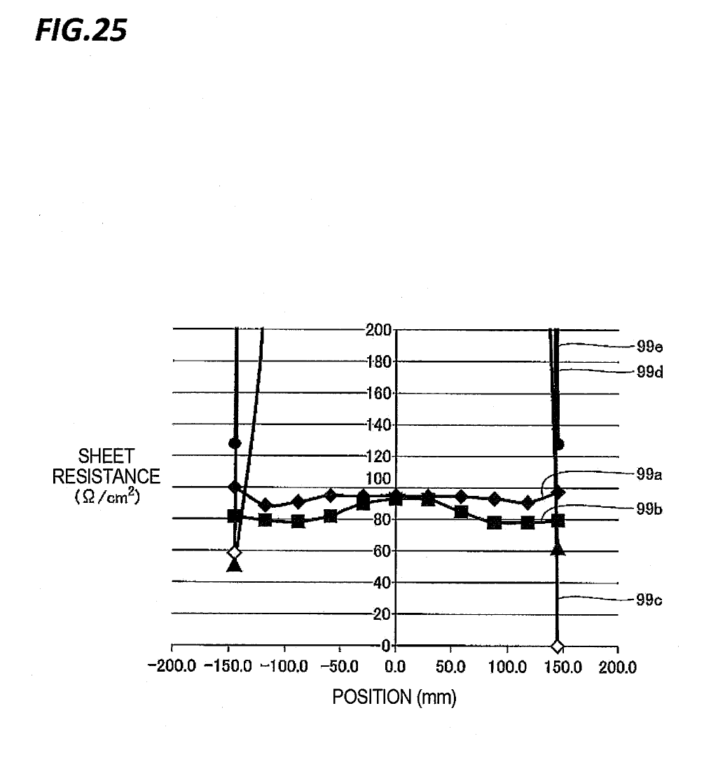

FIGS. 24 and 25 are graphs showing a relationship between a position and a sheet resistance of a substrate to be processed W when hydrogen (H₂) is added as a dilution gas. In FIGS. 24 and 25, like FIGS. 15 and 16, the vertical axis represents sheet resistance (Ω/cm²) and the horizontal axis represents position (mm) in the substrate to be processed W. FIG. 24 having a wider range of vertical axis shows a range of 0 to 3000 Ω/cm² and FIG. 25 having a narrower range of vertical axis shows a range of 0 to 200 Ω/cm².

In FIGS. 24 and 25, black diamonds and a solid line 99a are for a hydrogen gas flow rate of 1 sccm in the total gas flow rate of 1000 sccm, black squares and a solid line 99b are for a hydrogen gas flow rate of 2.5 sccm, white diamonds and a solid line 99c are for a hydrogen gas flow rate of 5 sccm, black triangles and a solid line 99d are for a hydrogen gas flow rate of 10 sccm, and black circles and a solid line 99e are for a hydrogen gas flow rate of 25 sccm. It is here noted that only one of the graphs has detailed indications.

Referring to FIGS. 24 and 25, when the flow rate of hydrogen gas is 1 sccm and 2.5 sccm, the sheet resistance decreases and in-plane uniformity is improved. Accordingly, by supplying hydrogen of equal to or more than 1 sccm and equal to or less than 2.5 sccm in the total flow rate of 1000 sccm, better electric characteristics and higher in-plane uniformity can be achieved. In this case, a relationship of 9.0E+13 m⁻²·sec⁻¹<flux F₁ of As atoms supplied in a direction perpendicular to the substrate to be processed<4.0E+14 m⁻²·sec⁻¹ is preferably established.

That is, when the total flow rate of doping gas and inert gas for plasma excitation is set to 1000 sccm, the plasma processing may be performed on the substrate to be processed by supplying a hydrogen gas with a flow rate of equal to or more than 1 sccm and equal to or less than 2.5 sccm.

Although it has been illustrated in the above exemplary embodiments that a silicon substrate is used as the substrate to be processed, the present disclosure is not limited thereto but may be well applied to doping in interlayer films.

In addition, although it has been illustrated in the above exemplary embodiments that the plasma processing is performed using a microwave generated by a radial line slot antenna including a slot antenna plate, the present disclosure is not limited thereto but may be applied to a plasma doping apparatus which generates plasma using a microwave generated by a comb-like antenna or a plasma doping apparatus which generates plasma using a microwave emitted from slots.

While the exemplary embodiments of the present disclosure has been shown and described with reference to the drawings, the present disclosure is not limited to the disclosed embodiments. Rather, the disclosed embodiments may be changed and modified in different ways without departing from the spirit and scope of the present disclosure defined in Claims and equivalents thereof.

### DESCRIPTION OF SYMBOL

11, 61, 71, 76: FinFET type semiconductor device, 12, 62, 73, 78, 82: silicon substrate, 13, 63: surface, 14, 64, 65, 72, 77: fin, 15: gate, 16: source, 17: drain, 28: control unit, 29: temperature adjusting mechanism, 31: plasma doping apparatus, 32: processing container, 33, 46, 47: gas supplying unit, 34: holding table, 35: microwave generator, 36: dielectric window, 37: slot antenna plate, 38: dielectric member, 39: plasma generating mechanism, 40: slot hole, 41: bottom portion, 42: side wall, 43: exhaust hole, 44: cover unit, 45: O-ring, 48: bottom, 49: gas supplying system, 30, 50: gas supplying hole, 51: tube-like supporter, 52: cooling jacket, 53: matching, 54: mode converter, 55: wave guide, 56: coaxial wave guide, 57: concave portion, 58: high-frequency power supply, 59: matching unit, 60: circulation path, 66, 67, 69: side wall, 68: upper wall, 70: region, 74, 79: photoresist layer, 75: dotted line, 80: plasma diffusion region, 81: MOS type semiconductor device, 83: element isolation region, 84a: p-type well, 84b: n-type well, 85a: high concentration n-type impurity diffusion region, 85b: high concentration p-type impurity diffusion region, 86a: n-type impurity diffusion region, 86b: p-type impurity diffusion region, 87; gate oxide film, 88: gate electrode, 89: gate side wall, 91: insulating film, 92: contact hole, 93; hole filling electrode, 94: metal wiring layer, 95a, 95b, 95c, 95d, 95e, 95f, 95g, 96a, 96b, 97a, 97b, 97c, 97d, 97e, 99a, 99b, 99c, 99d, 99e: solid line, 98a, 98b, 98c, 98d: region.

1. A plasma doping apparatus which performs doping by injecting dopants into a substrate to be processed, the apparatus comprising:
a processing container in which dopants are injected into the substrate to be processed;
a gas supplying unit configured to supply a doping gas and an inert gas for plasma excitation into the processing container;
a holding table disposed in the processing container and configured to hold the substrate to be processed;
a plasma generating mechanism configured to generate plasma in the processing container using a microwave;
a pressure adjusting mechanism configured to adjust a pressure in the processing container; and
a control unit configured to control the plasma doping apparatus,
wherein the control unit controls the pressure adjusting mechanism to set the pressure in the processing container to be equal to or more than 100 mTorr and less than 500 mTorr such that a plasma processing is performed on the substrate to be processed using the plasma generated by the plasma generating mechanism.

2-3. (canceled)

4. The plasma doping apparatus of claim 1, wherein, after the plasma processing is performed on the substrate to be processed, the control unit controls the pressure in the processing container to be set to a pressure lower than the pressure set when the plasma processing is performed on the substrate to be processed such that another plasma processing is performed on the substrate to be processed using the generated plasma.

5. The plasma doping apparatus of claim 4, wherein the pressure lower than the pressure set when the plasma processing is performed on the substrate to be processed is less than 100 mTorr.

6. The plasma doping apparatus of claim 1, wherein the doping gas includes at least one gas selected from a group consisting of B₂H₆, PH₃, AsH₃, GeH₄, CH₄, NH₃, NF₃, N₂, HF, and SiH₄.

7. The plasma doping apparatus of claim 1, wherein the inert gas for plasma excitation includes at least one gas selected from a group consisting of He, Ne, Ar, Kr, and Xe.

8. The plasma doping apparatus of claim 1, wherein the plasma generating mechanism is provided with a microwave generator configured to generate a microwave for plasma excitation, a dielectric window configured to transmit the microwave generated by the microwave generator through the processing container, and a slot antenna plate formed with a plurality of slot holes and configured to emit the microwave to the dielectric window.

9-20. (canceled)

21. A plasma doping method of performing doping by injecting dopants into a substrate to be processed, comprising:
holding a substrate to be processed on a holding table which is disposed in a processing container;
supplying an arsenic (As)-containing doping gas and an inert gas for plasma excitation into the processing container;
generating plasma in the processing container using a microwave; and
setting a pressure in the processing container to be equal to or more than 100 mTorr and less than 500 mTorr and establishing a relationship of 5.0E+13 m⁻²·sec⁻¹<flux F₁ of As atoms supplied in a direction perpendicular to the substrate to be processed<1.0E+14 m⁻²·sec⁻¹, thereby performing a plasma processing on the substrate to be processed.

22. The plasma doping method of claim 21, wherein the plasma processing is performed on the substrate to be processed by setting the pressure in the processing container to be equal to or more than 100 mTorr and less than 150 mTorr and establishing a relationship of 7.0E+13 m⁻²·sec⁻¹<flux F₁ of As atoms supplied in a direction perpendicular to the substrate to be processed<9.0E+13 m⁻²·sec⁻¹.

23. The plasma doping method of claim 21, wherein the plasma processing is performed on the substrate to be processed by supplying hydrogen at a flow rate of equal to or more than 1 sccm and equal to or less than 2.5 sccm, assuming that the total flow rate of the doping gas and the inert gas for plasma excitation is 1000 sccm.
